(19) United States
(12) Patent Application Publication
(10) Pub. No.: US 2025/0343156 A1
(43) Pub. Date: Nov. 6, 2025

(54) SEMICONDUCTOR PACKAGE AND SEMICONDUCTOR PACKAGE MANUFACTURING METHOD

(71) Applicant: SAMSUNG ELECTRONICS CO., LTD., SUWON-SI (KR)

(72) Inventors: Jungsoo KIM, Suwon-si (KR); Soomoon PARK, Suwon-si (KR); Hyemin JO, Suwon-si (KR)

(21) Appl. No.: 19/028,075

(22) Filed: Jan. 17, 2025

(30) Foreign Application Priority Data
May 2, 2024 (KR) 10-2024-0058449

(51) Int. Cl. H01L 23/544; H01L 21/56; H01L 23/00; H01L 23/31

(52) U.S. Cl. CPC H01L 23/544; H01L 21/563; H01L 23/3178; H01L 23/3185; H01L 24/16; H01L 2223/5448; H01L 2224/16227

(57) ABSTRACT

A semiconductor package includes: a semiconductor substrate on which a redistribution layer is formed; a semiconductor chip having a first surface that is disposed opposite the semiconductor substrate; a bump connecting the semiconductor chip to the redistribution layer; and a molding layer at least partially surrounding the semiconductor chip, wherein the first surface of the semiconductor chip includes: a trench area where one or more trenches, which have a closed loop shape and are concave, are positioned; a first area surrounded by the trench area; and a second area positioned on an outer side of the trench area, and the first surface of the semiconductor chip is exposed to an outside of the molding layer at least through the first area.

### CROSS-REFERENCE TO RELATED APPLICATION

This application claims priority under 35 U.S.C. § 119 to Korean Patent Application No. 10-2024-0058449 filed on May 2, 2024, in the Korean Intellectual Property Office, the disclosure of which is incorporated by reference herein in its entirety.

### TECHNICAL FIELD

Embodiments of the present inventive concept relate to a semiconductor package and a semiconductor package manufacturing method.

### DISCUSSION OF THE RELATED ART

As electronic devices become lighter and higher performing, it also becomes desirable for semiconductor packages to be miniaturized. To implement semiconductor packages that are miniaturized, light, high-performance, large-capacity, and high-reliability, semiconductor packages with a structure in which semiconductor chips are stacked on each other in multiple levels are currently under development.

### SUMMARY

According to an embodiment of the present inventive concept, a semiconductor package includes: a semiconductor substrate on which a redistribution layer is formed; a semiconductor chip having a first surface that is disposed opposite the semiconductor substrate; a bump connecting the semiconductor chip to the redistribution layer; and a molding layer at least partially surrounding the semiconductor chip, wherein the first surface of the semiconductor chip includes: a trench area where one or more trenches, which have a closed loop shape and are concave, are positioned; a first area surrounded by the trench area; and a second area positioned on an outer side of the trench area, and the first surface of the semiconductor chip is exposed to an outside of the molding layer at least through the first area.

According to an embodiment of the present inventive concept, a semiconductor package includes: a semiconductor substrate on which a redistribution layer is formed; a semiconductor chip having a first surface that is disposed opposite the semiconductor substrate; a bump connecting the semiconductor chip to the redistribution layer; and a molding layer at least partially surrounding the semiconductor chip, wherein the semiconductor chip includes: a first trench formed to be concave in the first surface along a periphery of the semiconductor chip; and a second trench formed to be concave in the first surface along the periphery of the semiconductor chip while surrounding the first trench, wherein the first surface of the semiconductor chip includes a first area and a second area, wherein the first area is surrounded by the first trench, wherein the second area extends from an outer side of the second trench, and wherein the first surface of the semiconductor chip is exposed to an outer side of the molding layer at least through the first area.

According to an embodiment of the present inventive concept, a method of manufacturing a semiconductor package includes: manufacturing a half-finished package in which a plurality of semiconductor chips are connected to a semiconductor substrate; encapsulating the half-finished package by molding the half-finished package by using a molding material; mounting a solder ball on the semiconductor substrate; and performing singulation on the half-finished package, wherein the manufacturing of the half-finished package includes forming one or more trenches in inactive surfaces of the semiconductor chips along peripheries of the semiconductor chips.

### BRIEF DESCRIPTION OF THE DRAWINGS

The above and other aspects of the present inventive concept will become more apparent by describing in detail embodiments thereof, with reference to the accompanying drawings, in which:

FIG. 1A is a perspective view schematically illustrating a semiconductor package according to an embodiment of the present inventive concept;

FIG. 1B is a cross-sectional view of the semiconductor package, taken along line Ib-Ib, of FIG. 1A;

FIG. 1C is a plan view of a semiconductor package according to an embodiment of the present inventive concept;

FIG. 2A is a plan view of a semiconductor package according to an embodiment of the present inventive concept;

FIG. 2B is a plan view of a semiconductor package according to an embodiment of the present inventive concept;

FIG. 2C is a plan view of a semiconductor package according to an embodiment of the present inventive concept;

FIG. 3 is a plan view of a semiconductor package according to an embodiment of the present inventive concept;

FIG. 4A is a cross-sectional view of a semiconductor package according to an embodiment of the present inventive concept;

FIG. 4B is a plan view of a semiconductor package according to an embodiment of the present inventive concept;

FIG. 4C is a plan view of a semiconductor package according to an embodiment of the present inventive concept;

FIG. 5 is a plan view of a semiconductor package according to an embodiment of the present inventive concept;

FIG. 6A is a perspective view of a semiconductor package according to an embodiment of the present inventive concept;

FIG. 6B is a cross-sectional view of the semiconductor package, taken along line VIb-VIb, of FIG. 6A;

FIG. 6C is a plan view of a semiconductor package according to an embodiment of the present inventive concept;

FIG. 7A is a perspective view of a semiconductor package according to an embodiment of the present inventive concept;

FIG. 7B is a cross-sectional view of the semiconductor package, taken along line VIIb-VIIb, of FIG. 7A of the present inventive concept;

FIG. 7C is a plan view of a semiconductor package according to an embodiment of the present inventive concept;

FIG. 7D is a plan view of a semiconductor package according to an embodiment of the present inventive concept;

FIG. 8A is a perspective view of a semiconductor package according to an embodiment of the present inventive concept;

FIG. 8B is a cross-sectional view of the semiconductor package, taken along line VIIIb-VIIIb, of FIG. 8A;

FIG. 8C is a plan view of a semiconductor package according to an embodiment of the present inventive concept;

FIG. 9A is a cross-sectional view of a semiconductor package according to an embodiment of the present inventive concept;

FIG. 9B is a plan view of a semiconductor package according to an embodiment of the present inventive concept;

FIG. 10 is a flowchart of a semiconductor package manufacturing method according to an embodiment of the present inventive concept;

FIG. 11A illustrates a half-finished package manufactured by a package manufacturing process according to an embodiment of the present inventive concept;

FIG. 11B illustrates an encapsulation process according to an embodiment of the present inventive concept;

FIG. 11C illustrates a solder ball mounting process according to an embodiment of the present inventive concept; and

FIG. 11D illustrates a singulation process according to an embodiment of the present inventive concept.

### DETAILED DESCRIPTION OF THE EMBODIMENTS

Hereinafter, embodiments of the present inventive concept will be described in detail with reference to the accompanying drawings. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular embodiments only and is not intended to be limiting. The singular forms “a”, “an”, and “the” are intended to include the plural forms as well, unless the context clearly indicates otherwise.

Terms, such as those defined in commonly used dictionaries, are to be interpreted as having a meaning that is consistent with their meaning in the context of the relevant art and the present inventive concept, and are not to be interpreted in an idealized or overly formal sense unless expressly so defined herein.

When describing the embodiments with reference to the accompanying drawings, like reference numerals refer to like components and a repeated description related thereto will be omitted or briefly discussed. In addition, to the extent that the description of various elements is omitted, it may be assumed that these elements are at least similar to corresponding elements that have already been described.

In addition, in the description of the components, terms such as first, second, A, B, (a), (b) or the like may be used herein when describing components of embodiments of the present inventive concept. These terms are used only for the purpose of distinguish one component from another component, and the nature, the sequences, or the orders of the components are not limited by the terms. In other words, the components are not limited by these terms. It should be noted that if one component is described as being “connected,” “coupled” or “joined” to another component, the former may be directly “connected,” “coupled,” and “joined” to the latter or “connected”, “coupled”, and “joined” to the latter via another component (e.g., an intervening component).

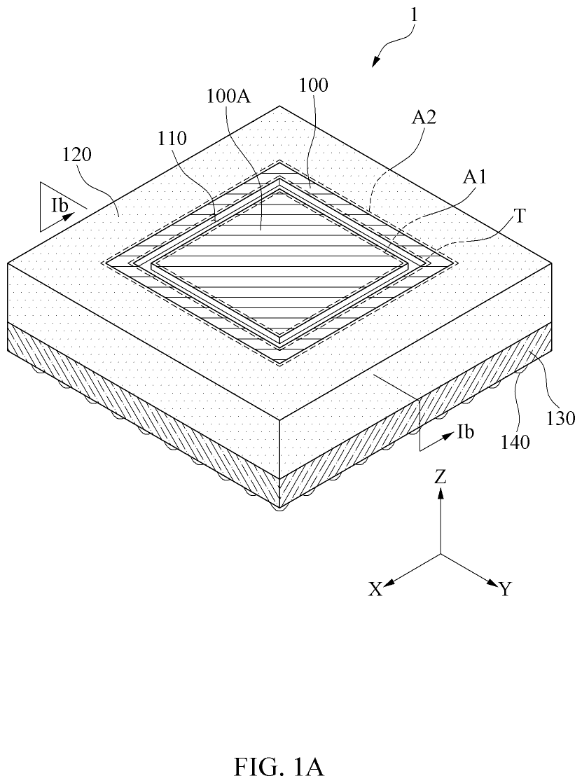

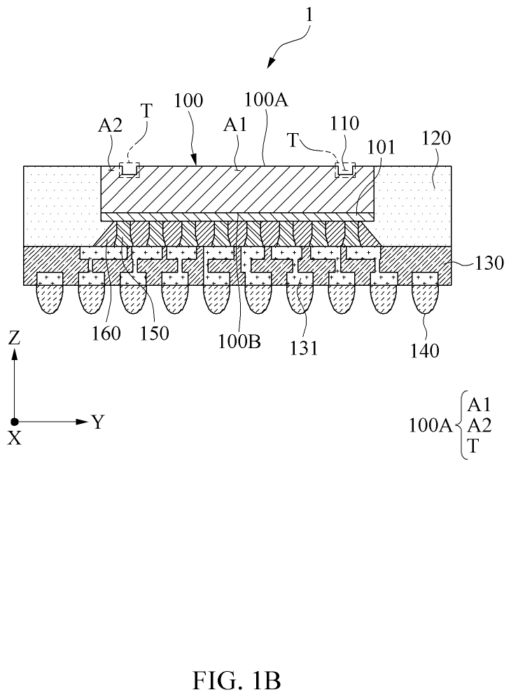

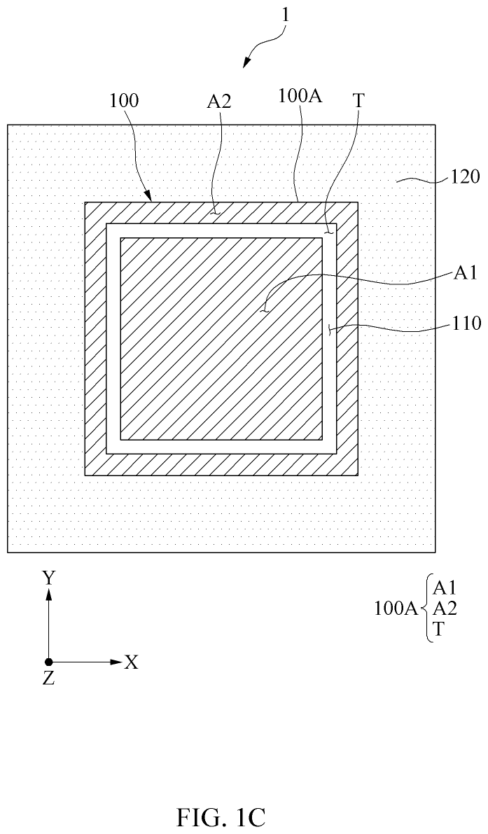

FIG. 1A is a perspective view schematically illustrating a semiconductor package according to an embodiment of the present inventive concept. FIG. 1B is a cross-sectional view of the semiconductor package, taken along line Ib-Ib, of FIG. 1A. FIG. 1C is a plan view of the semiconductor package according to an embodiment of the present inventive concept.

Referring to FIG. 1A, a semiconductor package 1 may include a semiconductor chip 100, a molding layer 120 at least partially surrounding the semiconductor chip 100, a semiconductor substrate 130 supporting the semiconductor chip 100 and the molding layer 120, and a plurality of connecting terminals 140 arranged under the semiconductor substrate 130. For example, the semiconductor package 1 may be a ball grid array (BGA) in which the connecting terminals 140 are formed as solder balls.

The semiconductor package 1 according to an embodiment of the present inventive concept may be configured such that a portion of the surface of the semiconductor chip 100 is exposed to the outside. For example, the semiconductor chip 100 may be exposed to the outside of the semiconductor package 1 through a first surface 100A (e.g., the surface facing in the +Z direction of FIG. 1) opposite the semiconductor substrate 130. In some examples, a upper surface of the molding layer 120 may be coplanar with the first surface 100A of the semiconductor chip 100. For example, the first surface 100A of the semiconductor chip 100 may be not contact with the molding layer 120

For example, a large portion of the surface of the semiconductor chip 100 may be configured to be surrounded and covered by the molding layer 120, but the molding layer 120 may be omitted from at least a portion of the first surface 100A of the semiconductor chip 100.

A trench 110 may be formed in the first surface 100A of the semiconductor chip 100. The trench 110 may be formed to be concave inward (e.g., in the −Z direction) from the first surface 100A of the semiconductor chip 100. The trench 110 may form a closed loop in the first surface 100A of the semiconductor chip 100. The first surface 100A of the semiconductor chip 100 may be divided into a trench area T where the trench 110 is formed, a first area A1 that is surrounded by the trench area T, and a second area A2 that is positioned on the outer side of the trench area T. For example, the trench area T may be disposed between the first area A1 and the second area A2. The molding layer 120 may be omitted from the first area A1. For example, during the molding process of forming the molding layer 120 through a molding material, the trench 110 may function as a boundary line to accommodate the molding material so that the molding material flowing along the first surface 100A might not enter the first area A1. The first surface 100A of the semiconductor chip 100 may be exposed to the outside of the semiconductor package 1 at least through the first area A1. The semiconductor chip 100 may discharge heat to the outside of the semiconductor package 1 through the first surface 100A that is exposed to the outside.

Referring to FIG. 1B, the semiconductor package 1 may include the semiconductor substrate 130 (or substrate) on which a redistribution layer 131 is formed, the semiconductor chip 100 (or die), a bump 150 connecting the semiconductor chip 100 to the redistribution layer 131, an underfill layer 160, the connecting terminals 140, and the molding layer 120 surrounding the semiconductor chip 100.

The redistribution layer 131 may be formed on the semiconductor substrate 130. For example, the redistribution layer 131 may include a plurality of redistribution line patterns, a plurality of redistribution vias, and a redistribution insulating layer. The redistribution insulating layer may be formed from, for example, photo imageable dielectric (PID) or photosensitive polyimide (PSPI). The redistribution line patterns and the redistribution vias may include, for example, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or an alloy thereof, but the present inventive concept is not limited thereto. As an example, the redistribution line patterns and the redistribution vias may be formed by stacking the metal or alloy on a seed layer including, for example, titanium, titanium nitride, or titanium tungsten.

The semiconductor chip 100 may be disposed on the semiconductor substrate 130. For example, the semiconductor chip 100 may be disposed above (e.g., the +Z direction of FIG. 1B) of the semiconductor substrate 130. The semiconductor chip 100 may include the first surface 100A and a second surface 100B. The first surface 100A is an inactive surface, and the second surface 100B is an active surface that is opposite to the first surface 100A. The semiconductor chip 100 may be disposed with the second surface 100B facing the semiconductor substrate 130, and the first surface 100A facing in a direction that is opposite to the semiconductor substrate 130. The first surface 100A of the semiconductor chip 100 may be exposed upward (e.g., in the +Z direction) from the semiconductor package 1. For example, the first surface 100A of the semiconductor chip 100 may be upper surface of the semiconductor chip 100, and the second surface 100B of the semiconductor chip 100 may be lower surface of the semiconductor chip 100.

The trench 110 concaved downward may be formed in the first surface 100A of the semiconductor chip 100. For example, the trench 110 may be formed in the surface of the semiconductor chip 100 through laser processing, but the method of forming the trench 110 is not limited thereto. Based on the trench area T where the trench 110 is formed, the first surface 100A of the semiconductor chip 100 may be divided into the first area A1 and the second area A2. The first area A1 may be surrounded by the trench area T, and the second area A2 extends from the trench area T to the periphery of the first surface 100A. A chip pad 101 may be disposed on the second surface 100B of the semiconductor chip 100.

The semiconductor chip 100 may include a plurality of semiconductor devices that are formed on the second surface 100B being an active surface. The semiconductor devices may include various micro-electronic devices such as, for example, a metal-oxide-semiconductor field-effect transistor (MOSFET) such as a complementary metal-insulator-semiconductor transistor (CMOS transistor), a system large-scale integration (LSI), an active device, a passive device, and the like. The plurality of semiconductor devices may be electrically separated from each other by an insulating film.

The chip pad 101 may be electrically connected to the redistribution layer 131 of the semiconductor substrate 130. The chip pad 101 may include a conductive layer including, for example, a metal, a metal nitride, a conductive carbon, or a combination thereof. The chip pad 101 may include, for example, copper (Cu), cobalt (Co), aluminum (Al), tin (Sn), nickel (Ni), gold (Au), silver (Ag), tungsten (W), tungsten nitride (WN), titanium (Ti), titanium nitride (TiN), tantalum (Ta), tantalum nitride (TaN), ruthenium (Ru), platinum (Pt), or a combination thereof. The chip pad 101 may be electrically connected to the plurality of semiconductor devices that are formed on the semiconductor chip 100.

The bump 150 may connect the semiconductor chip 100 to the redistribution layer 131 of the semiconductor substrate 130. The bump 150 may be disposed between the semiconductor chip 100 and the semiconductor substrate 130 to electrically and mechanically connect the semiconductor chip 100 and the semiconductor substrate 130 to each other. A plurality of bumps 150 may be arranged to connect the semiconductor chip 100 and the semiconductor substrate 130 to each other.

The underfill layer 160 may be disposed between the semiconductor chip 100 and the semiconductor substrate 130. The underfill layer 160 may be formed of a polymer material, for example, an epoxy material. The underfill layer 160 may be disposed to fill the space between the plurality of bumps 150 and connect the semiconductor chip 100 and the semiconductor substrate 130 to each other. For example, the underfill layer 160 may seal the plurality of bumps 150. The underfill layer 160 may increase the bonding force that is formed between the semiconductor chip 100 and the semiconductor substrate 130 through the plurality of bumps 150.

The connecting terminals 140 may be connected to the semiconductor substrate 130. The semiconductor package 1 may be electrically connected to, for example, another semiconductor package 1, a motherboard, or the like through the connecting terminals 140. The plurality of connecting terminals 140 may be arranged under (e.g., the −Z direction of FIG. 1B) the semiconductor substrate 130. For example, the plurality of connecting terminals 140 may be disposed on a lower surface of the semiconductor substrate 130. The connecting terminals 140 may be, for example, solder balls, but are not limited thereto.

The molding layer 120 may protect the semiconductor chip 100 by surrounding the semiconductor chip 100. For example, the molding layer 120 may be formed of an epoxy mold compound (EMC). The EMC may include, for example, a resin, a filler, and a curing agent. The molding layer 120 may be disposed on the semiconductor substrate 130 to surround the perimeter, between the first surface 100A and the second surface 100B, of the semiconductor chip 100. The molding layer 120 may be formed to have a horizontal surface of the same shape as the horizontal surface of the semiconductor substrate 130. For example, based on the side surface of the semiconductor package 1 that is parallel to the Z-axis direction of FIG. 1B, the side surface of the molding layer 120 and the side surface of the semiconductor substrate 130 may be disposed substantially on the same plane to form the side surface of the semiconductor package 1.

The molding layer 120 may be omitted from the first surface 100A of the semiconductor chip 100. For example, the molding layer 120 may be omitted from the entire first surface 100A of the semiconductor chip 100 so that the entire first surface 100A of the semiconductor chip 100 may be exposed to the outside. In some examples, the molding layer 120 may extend from the periphery of the first surface 100A to cover at least a portion of the first surface 100A. In this case, the molding layer 120 may be omitted from the first area A1 of the first surface 100A. For example, the semiconductor chip 100 may be exposed to the outside at least through the first area A1 that is positioned inside the trench 110.

Referring to FIG. 1C, in a state in which the first surface 100A is viewed, the semiconductor chip 100 may be surrounded by the molding layer 120. The first surface 100A of the semiconductor chip 100 may be formed to have a polygonal shape, such as a substantially square shape. In an example, the trench 110 may be formed in the first surface 100A to form a square closed loop along the perimeter of the semiconductor chip 100. For example, the trench 110 may be formed with a square closed loop shape in the peripheral area of that first surface 100A and may be formed with a predetermined distance from an edge of the first surface 100A. In an example, the trench 110 may be formed in the first surface 100A with a predetermined width along the side of the first surface 100A. The first area A1 surrounded by the trench area T may form a substantially square shape. The trench 110 may be formed on the first surface 100A in a predetermined depth, but the depth of the trench 110 may vary depending on where it is formed. For example, the trench 110 may be formed to have a greater depth at portions of the first surface 100A that are more adjacent to the corners than the sides of the first surface 100A. However, this is merely an example, and embodiments are not limited thereto. The trench 110 may be formed adjacent to the periphery of the first surface 100A. In an example, the trench 110 may be formed at a predetermined interval from the periphery of the first surface 100A. In an example, in a state in which the first surface 100A is viewed, core areas of the semiconductor chip 100, for example, core areas functioning as a central processing unit (CPU), a graphics processing unit (GPU), and a neural processing unit (NPU), may overlap within the first area A1.

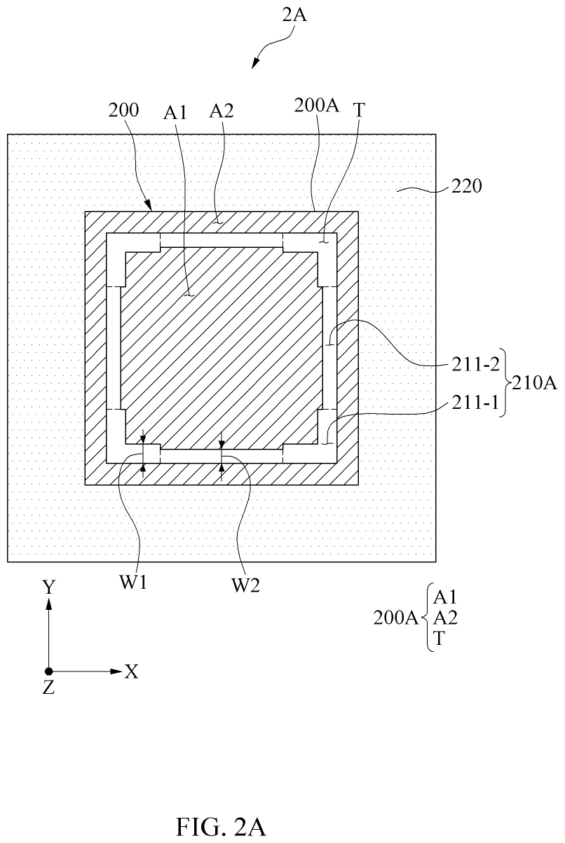

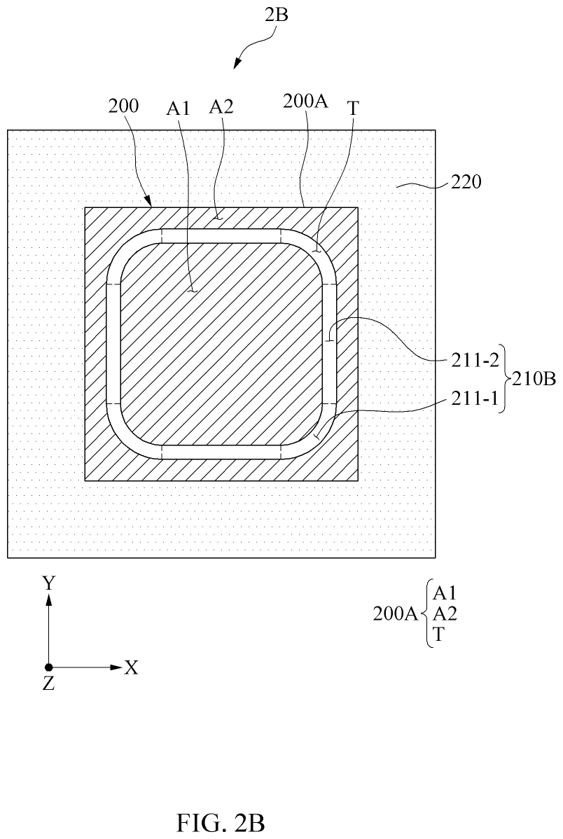

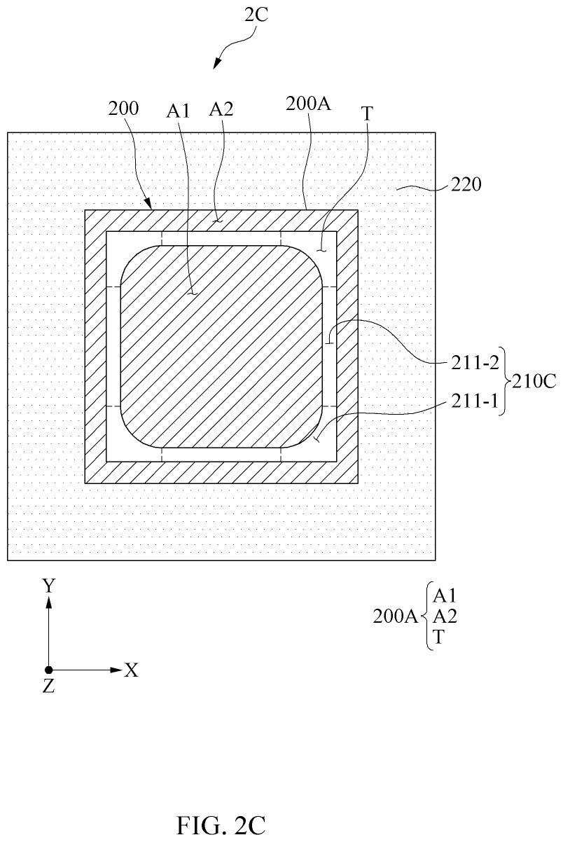

FIG. 2A is a plan view of a semiconductor package according to an embodiment of the present inventive concept. FIG. 2B is a plan view of a semiconductor package according to an embodiment of the present inventive concept. FIG. 2C is a plan view of a semiconductor package according to an embodiment of the present inventive concept.

Referring to FIG. 2A, in a semiconductor package 2A according to an embodiment of the present inventive concept, a semiconductor chip 200 may be exposed to the outside through a first surface 200A that is an inactive surface. The first surface 200A of the semiconductor chip 200 may be surrounded by a molding layer 220. A trench 210A may be formed to be concave in the first surface 200A of the semiconductor chip 200. In a state in which the first surface 200A is viewed, the trench 210A may be formed to extend in the perimeter direction of the semiconductor chip 200, thereby forming a trench area T with a closed loop. The first surface 200A may include a first area A1, which is disposed inside the trench area T, and a second area A2, which extends from the outside of the trench area T to the periphery of the first surface 200A. For example, the second area A2 is disposed between the trench area T and an edge of the first surface 200A.

In an example, the trench 210A may form a square ring-shaped trench area T along the perimeter of the semiconductor chip 200. For example, the trench 210A may include a plurality of first trench portions 211-1 and a plurality of second trench portions 211_2. The plurality of first trench portions 211_1 may be positioned at respective corners of the square ring shape of the trench area T, and the plurality of second trench portions 211-2 may be positioned on respective sides of the square ring shape of the trench area T to connect a pair of adjacent first trench portions 211-1 to each other. For example, the plurality of first trench portions 211_1 may be positioned at respective corners of the first surface 200A, and the plurality of second trench portions 211-2 may be positioned on respective sides of the first surface 200A to connect a pair of adjacent first trench portions 211-1 to each other. For example, in FIG. 2A, the trench 210A may include four first trench portions 211-1 forming the corners of the trench area T, and four second trench portions 211-2 forming the sides of the trench area T.

In an example, the first trench portions 211-1 and the second trench portions 211-2 may be formed to have different widths from each other. For example, the first trench portions 211-1 may have a first width W1, and the second trench portions 211-2 may have a second width W2 that is smaller than the first width W1. The first trench portions 211-1 and the second trench portions 211-2 may be formed to have different depths from each other. For example, the first trench portions 211-1 may be formed in the first surface 200A of the semiconductor chip 200 to have a greater depth than the second trench portions 211-2. However, the present inventive concept is not limited thereto. For example, the first trench portions 211-1 and the second trench portions 211-2 may be formed to have the same depth as each other.

The first trench portions 211-1 may accommodate a larger amount of molding material than the second trench portions 211-2. During the process of forming the molding layer 220 of a semiconductor package 2 using a molding material, a larger amount of molding material may be introduced from the top of the first surface 200A through the corner portions than the side portions of the first surface 200A. When the first trench portions 211-1 are configured to accommodate a larger amount of molding material than the second trench portions 211-2, the inflow of the molding material into the first area A1 may be more effectively prevented or reduced.

Referring to FIG. 2B, a trench 210B may be formed to be concave in the first surface 200A to form a square trench area T with rounded corners along the perimeter of the semiconductor chip 200. The first surface 200A may include a first area A1 disposed inside the trench area T and a second area A2 extending from the outside of the trench area T to the periphery of the first surface 200A.

The trench 210B may include four first trench portions 211-1 and four second trench portions 211-2. The four first trench portions 211-1 may form the corners of the trench area T, and the four second trench portions 211-2 may connect a pair of adjacent first trench portions 211-1 to each other and may form the sides of the trench area T. In an example, the first trench portions 211-1 may be formed substantially at a predetermined separation interval from the periphery of the first surface 200A, for example, a separation interval from the molding layer 220 that surrounds the first surface 200A. In a state in which the first surface 200A is viewed, the first trench portions 211-1 may be formed with the corners in a filleted shape. For example, the first trench portions 211-1 may have a curved shape. In this case, as the distance from a corner of the first surface 200A to an adjacent first trench portion 211-1 increases, the area of a portion of the second area A2 adjacent to the corner of the first surface 200A may expand. For example, considering that a larger amount of molding material is introduced through the corner portion of the first surface 200A during the process of molding the molding layer 220 using a molding material, the first trench portions 211-1 may be formed in a filleted shape so that the area of the second area A2 that is adjacent to the corner of the first surface 200A may expand.

Referring to FIG. 2C, a trench 210C may be formed to be concave in the first surface 200A to form a trench area T with a closed loop along the perimeter of the semiconductor chip 200. The trench 210C may be formed in the first surface 200A to form a substantially square trench area T. The first surface 200A may include a first area A1, which is disposed inside the trench area T, and a second area A2, which extends from the trench area T to the periphery of the first surface 200A. The trench 210C may include four first trench portions 211-1 and four second trench portions 211-2. The four first trench portions 211-1 may form the corners of the trench area T, and the four second trench portions 211-2 may connect a pair of adjacent first trench portions 211-1 to each other and may form the sides of the trench area T.

In an example, the first trench portions 211-1 may form a right-angled corner at the boundary with the second area A2 and form a filleted corner at the boundary with the first area A1. Accordingly, the first area A1 may have a square shape with rounded corners, and the second area A2 may have a square shape along the perimeter of the trench area T. In an example, the first trench portions 211-1 may be formed to have a greater depth than the second trench portions 211-2, but embodiments of the present inventive concept are not limited thereto.

For example, when the molding material is introduced from the top of the first surface 200A during the molding process, the first trench portions 211-1 may be configured to accommodate a larger amount of molding material than the second trench portions 211-2 for the same period of time.

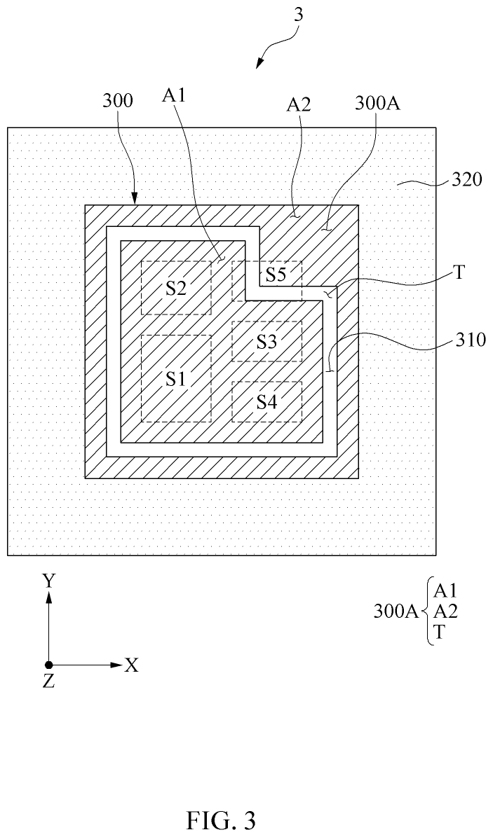

FIG. 3 is a plan view of a semiconductor package according to an embodiment of the present inventive concept.

Referring to FIG. 3, in a semiconductor package 3, a semiconductor chip 300 may be configured so that a first surface 300A being an inactive surface is exposed to the outside, and the first surface 300A may be surrounded by a molding layer 320. The semiconductor chip 300 may include a trench 310 that is formed to be concave in the first surface 300A. The trench 310 may form a trench area T having a closed loop shape from a plan view. The first surface 300A of the semiconductor chip 300 may include a first area A1, which is surrounded by the trench area T, and a second area A2, which extends from the outer side of the trench area T to the periphery of the first surface 300A. For example, the trench area T may form the boundary between the first area A1 and the second area A2.

In an example, the semiconductor chip 300 may include a plurality of core areas to perform different functions. The plurality of core areas may be located on the second surface 100B (See FIG. 1B) of the semiconductor chip 300. For example, the plurality of semiconductor devices may be located in each of the plurality of core areas. For example, the plurality of semiconductor devices located in the plurality of core areas may be of different types. For example, the respective core areas may correspond to the main heat-generating portions that affect the heat generation of the semiconductor chip 300.

In an example, the trench 310 may be formed to surround a set portion of the plurality of core areas formed in the semiconductor chip 300, from a plan view. For example, the plurality of core areas of the second surface of the semiconductor chip 300 may overlap in a vertical direction with the first area A1 of the first surface 300A of the semiconductor chip 300.

For example, in a case where a plurality of core areas S1, S2, S3, S4, and S5 are formed in the semiconductor chip 300 as shown in FIG. 3, the trench 310 may be formed in the first surface 300A to form the boundary between the first area A1 and the second area A2 while surrounding the periphery of some core areas S1, S2, S3, and S4 among the plurality of core areas. In this case, the core areas S1, S2, S3, and S4 which are located below the first area A1, may have relatively high heat generation compared to the remaining core area S5. For example, the core areas S1, S2, S3, and S4 which are located below the first area A1 may be areas where a CPU, a GPU, and an NPU function. For example, the trench 310 may be formed in the first surface 300A to surround the portions exhibiting the main heat generation characteristics in the semiconductor chip 300, thereby preventing the inflow of the molding material into the portion of the first surface 300A corresponding to the main heat-generating portions of the semiconductor chip 300.

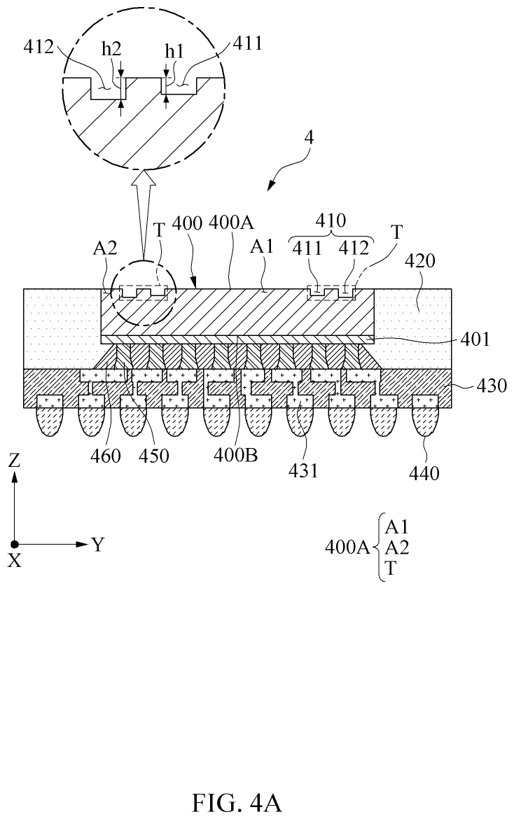

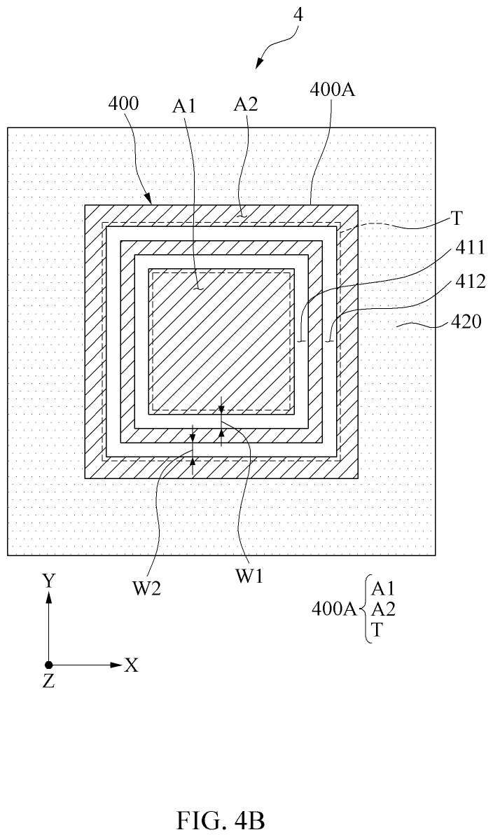

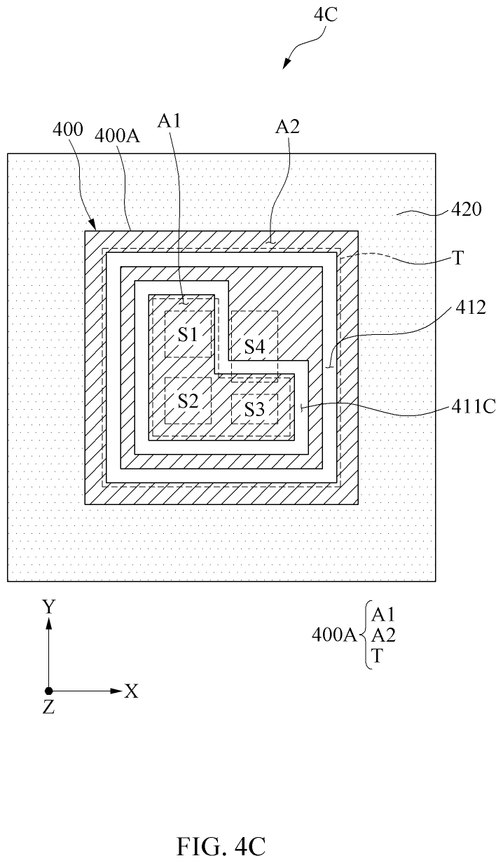

FIG. 4A is a cross-sectional view of a semiconductor package according to an embodiment of the present inventive concept. FIG. 4B is a plan view of the semiconductor package according to an embodiment of the present inventive concept. FIG. 4C is a plan view of a semiconductor package according to an embodiment of the present inventive concept.

Referring to FIGS. 4A and 4B, a semiconductor package 4 according to an embodiment of the present inventive concept may include a semiconductor chip 400, a molding layer 420 surrounding the semiconductor chip 400, a semiconductor substrate 430 on which a redistribution layer 431 is formed, a plurality of bumps 450 connecting the semiconductor chip 400 to the redistribution layer 431 of the semiconductor substrate 430, an underfill layer 460 disposed between the semiconductor chip 400 and the semiconductor substrate 430 to fill the gap that is between the plurality of bumps 450, and a connecting terminal 440.

The semiconductor chip 400 may include a first surface 400A, which is disposed opposite the semiconductor substrate 430, and a second surface 400B, which is disposed opposite the first surface 400A and faces toward the semiconductor substrate 430. The first surface 400A of the semiconductor chip 400 may be an inactive surface, and the second surface 400B may be an active surface. A chip pad 401 may be disposed on the second surface 400B of the semiconductor chip 400 and electrically connected to a plurality of semiconductor devices that are formed on the semiconductor chip 400. The semiconductor chip 400 may be exposed to the outside through the first surface 400A. The perimeter of the semiconductor chip 400 may be surrounded by the molding layer 420. In this case, the molding layer 420 may be omitted from the first surface 400A of the semiconductor chip 400. For example, the molding layer 420 does not cover the first surface 400A of the semiconductor chip 400.

The first surface 400A of the semiconductor chip 400 may include a trench area T where the trench 410 is formed, a first area A1 surrounded by the trench area T, and a second area A2 extending from the outer side of the trench area T to the periphery of the first surface 400A. A plurality of trenches 410 that are concave downward from the first surface 400A may be formed in the trench area T. For example, a first trench 411 surrounding the first area A1, and a second trench 412 spaced apart from the first trench 411 while surrounding the first trench 411 may be formed in the trench area T. In a state in which the first surface 400A is viewed as shown in FIG. 4B, the first trench 411 may extend to form a closed loop along the perimeter of the first area A1. The second trench 412 may extend to form a closed loop along the perimeter of the first trench 411. The plurality of trenches 410 may accommodate the molding material flowing across the second area A2 from the periphery of the first surface 400A, during the process of molding the molding layer 420 around the semiconductor chip 400, thereby minimizing or blocking the inflow of the molding material into the first area A1. The plurality of trenches 410 may sequentially accommodate the molding material from the outer side of the first surface 400A toward the first area A1. For example, the second trench 412 may primarily accommodate the molding material flowing across the second area A2, and the first trench 411 may secondarily accommodate the molding material flowing across the second trench 412.

In an example, of the plurality of trenches 410, a trench 410 that is adjacent to the second area A2 may be configured to accommodate a relatively large amount of molding material compared to a trench 410 that is adjacent to the first area A1. For example, the width W2 of the second trench 412 may be larger than the width W1 of the first trench 411. For example, the second trench 412 may be formed in the first surface 400A of the semiconductor chip 400 such that the depth H2 of the second trench H2 may be greater than the depth H1 of the first trench 411.

In a state in which the first surface 400A is viewed, core areas of the semiconductor chip 400, for example, core areas a CPU, a GPU, and an NPU may function, may overlap within the first area A1 that is surrounded by the first trench 411.

Referring to FIG. 4C, in a semiconductor package 4C, a semiconductor chip 400 may include a plurality of core areas S1, S2, S3, and S4 to perform different functions. The core areas S1, S2, S3, and S4 may exhibit the main heat generation characteristics in the semiconductor chip 400.

In an example, a plurality of trenches 410 formed in the first surface 400A may be formed in consideration of the heat generation characteristics of the plurality of core areas. For example, in a state in which the first surface 400A is viewed, a second trench 412 may be formed to surround the plurality of core areas S1, S2, S3, and S4, and a first trench 411C may be formed to surround at least some core areas S1, S2, and S3, exhibiting high heat generation characteristics, of the core areas S1, S2, S3, and S4 that are surrounded by the second trench 412. For example, when four core areas S1, S2, S3, and S4 are formed in the semiconductor chip 400 as shown in FIG. 4C, the second trench 412 adjacent to the second area A2 may be formed to surround the four core areas S1, S2, S3, and S4. During the process of forming a molding layer 420 by the second trench 412, the inflow of the molding material into a portion of the first surface 400A overlapping the core areas may be reduced or prevented. The first trench 411C formed inside the second trench 412 may be formed in a shape surrounding at least some core areas S1, S2, and S3 of the four core areas S1, S2, S3, and S4. In this case, the core areas S1, S2, and S3 that are surrounded by the first trench 411 may have relatively high heat generation compared to the other core area S4 that is not surrounded by the first trench 411. For example, the core areas S1, S2, and S3 surrounded by the first trench 411, for example, the core areas overlapping within the first area A1, may be areas where a CPU, a GPU, and an NPU are positioned.

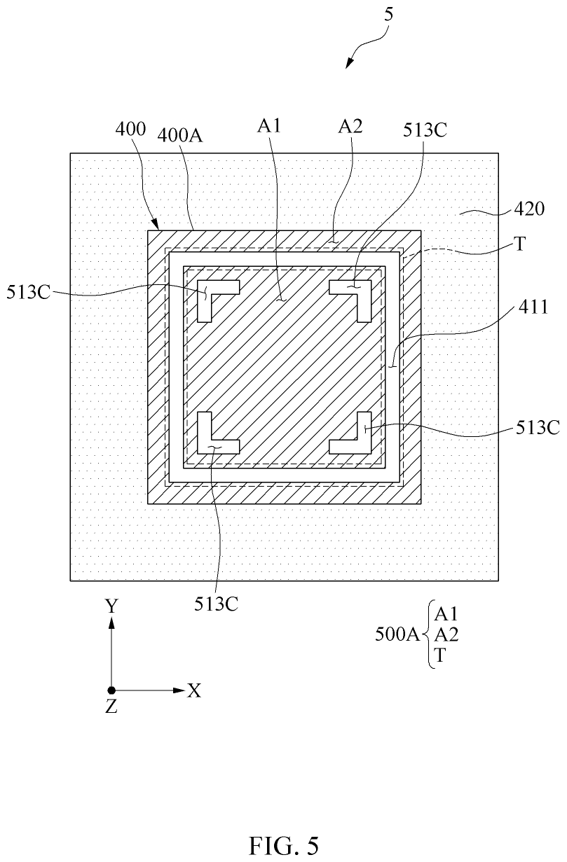

Referring to FIG. 5, in a semiconductor package 5 according to an embodiment of the present inventive concept, a first surface 500A of a semiconductor chip 500 may be exposed to the outside and may be an inactive surface. The first surface 500A of the semiconductor chip 500 may be surrounded by a molding layer 520. The first surface 500A of the semiconductor chip 500 may include a trench area T where the trench 510 is formed, a first area A1 surrounded by the trench area T, and a second area A2 extending from the outer side of the trench area T to the periphery of the first surface 500A.

One or more auxiliary trenches 513C may be formed to be concave in the first area A1 of the first surface 500A. The auxiliary trenches 513C may be disposed adjacent to the trench area T. The auxiliary trenches 513C may be disposed adjacent to a portion, which is vulnerable to inflow of a molding material, of the trench area T. For example, the auxiliary trenches 513C may be formed adjacent to the trench area T and adjacent to the corners of the first surface 500A. The plurality of auxiliary trenches 513C may be formed in the first area A1. In a state in which the first surface 500A is viewed, the auxiliary trenches 513C may be formed not to overlap portions exhibiting the main heat generation characteristics in the semiconductor chip 500. For example, during the process of molding the molding layer 520 of the semiconductor package 5, the auxiliary trenches 513C may accommodate the molding material that is introduced into the first area A1 across the trench area T.

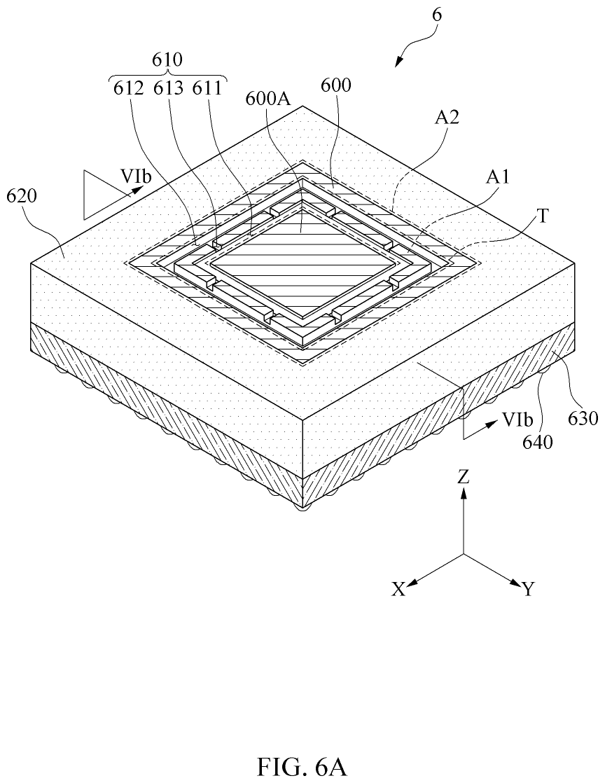

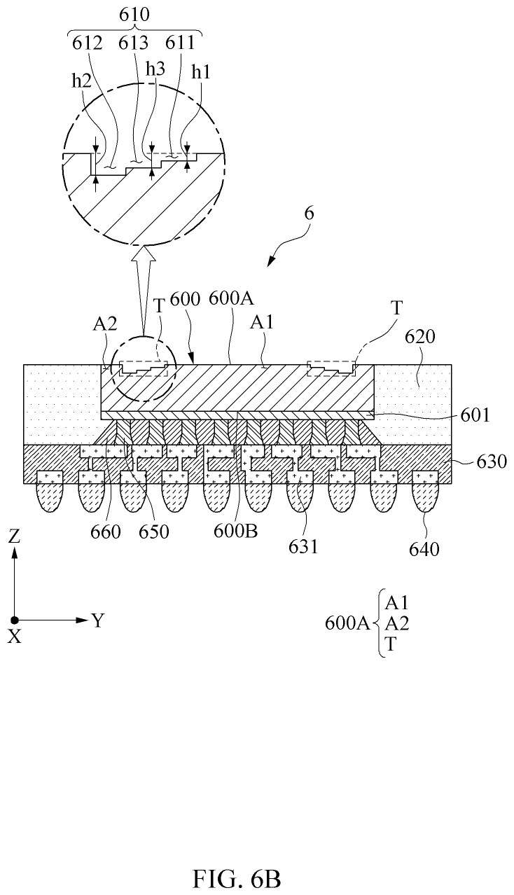

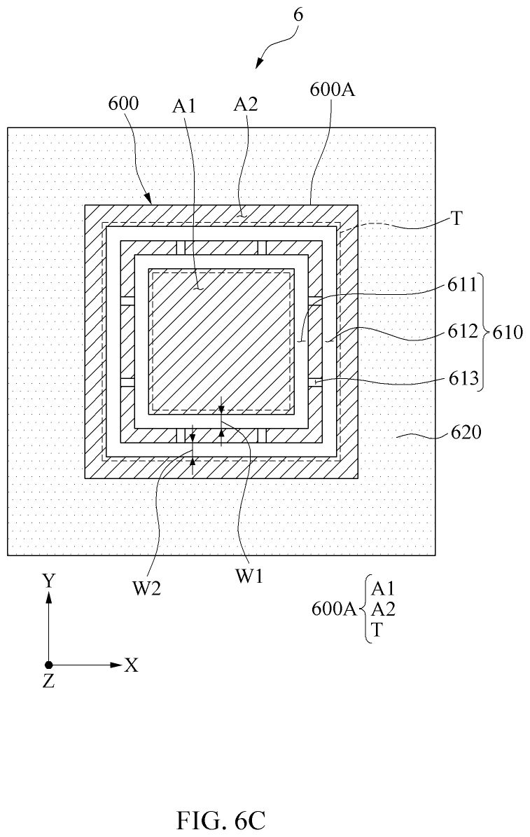

FIG. 6A is a perspective view of a semiconductor package according to an embodiment of the present inventive concept. FIG. 6B is a cross-sectional view of the semiconductor package, taken along line VIb-VIb, of FIG. 6A. FIG. 6C is a plan view of the semiconductor package according to an embodiment of the present inventive concept.

Referring to FIGS. 6A to 6C, a semiconductor package 6 according to an embodiment of the present inventive concept may include a semiconductor chip 600, a molding layer 620 surrounding the semiconductor chip 600, a semiconductor substrate 630 on which a redistribution layer 631 is formed, a plurality of bumps 650 connecting the semiconductor chip 600 to the redistribution layer 631 of the semiconductor substrate 630, an underfill layer 660 disposed between the semiconductor chip 600 and the semiconductor substrate 630 to fill the gap that is between the plurality of bumps 650, and a connecting terminal 640.

The semiconductor chip 600 may include a first surface 600A, which is disposed opposite the semiconductor substrate 630, and a second surface 600B, which is disposed opposite to the first surface 600A and to face toward the semiconductor substrate 630. The first surface 600A may be an inactive surface, and the second surface 600B may be an inactive surface. A chip pad 601 may be disposed on the second surface 600B of the semiconductor chip 600. The semiconductor chip 600 may be exposed to the outside of the semiconductor package 6 through the first surface 600A. The semiconductor chip 600 may be surrounded by the molding layer 620. The molding layer 620 may be omitted from the first surface 600A of the semiconductor chip 600.

The first surface 600A of the semiconductor chip 600 may include a trench area T, a first area A1, and a second area A2. The trench area T may be an area where a plurality of trenches 610 are formed to be concaved downward from the first surface 600A. The first area A1 may be surrounded by the trench area T, and the second area A2 may be positioned on the outer side of the trench area T. The plurality of trenches 610 may be formed in the trench area T. For example, in a state in which the first surface 600A is viewed, a first trench 611 surrounding the first area A1, a second trench 612 spaced apart from the first trench 611 while surrounding the first trench 611, and one or more connecting trenches 613 formed to connect the first trench 611 and the second trench 612 to each other may be formed in the trench area T.

The second trench 612 may be configured to primarily accommodate the molding material introduced along the periphery of the first surface 600A during the process of manufacturing the semiconductor chip 600. The first trench 611 may be configured to secondarily accommodate the molding material that is introduced into the first area A1 as the molding material exceeds the capacity of the second trench 612. The second trench 612 may be configured to accommodate a larger amount of molding material than the first trench 611. For example, the first trench 611 may be formed to have a first depth h1, and the second trench 612 may be formed to have a second depth h2 that is greater than the first depth h1. For example, the first trench 611 may be formed to have a first width w1, and the second trench 612 may be formed to have a second width w2 that is greater than the first width w1.

The connecting trenches 613 may induce the molding material to flow into the first trench 611 from the second trench 612 when the amount of molding material flowing into the second trench 612 exceeds the capacity of the second trench 612. For example, the connecting trenches 613 may be formed in the first surface 600A with a third depth h3 that is greater than the first depth h1 and less than the second depth h2. When the molding material introduced into the second trench 612 reaches the first depth h1 with respect to the first surface 600A, the molding material may be introduced from the second trench 612 to the first trench 611 through the connecting trenches 613. As the first trench 611 and the second trench 612 are connected to each other through the connecting trenches 613, the capacity of accommodating the molding material in the trench area T may increase, and the inflow of the molding material into the trench area T where the trenches 610 are not formed may be reduced or prevented.

Referring to FIG. 6C, a plurality of connecting trenches 613 may be formed to be spaced apart from each other while in the trench area T and between the first trench 611 and the second trench 612. It should be noted that the number and positions of the connecting trenches 611 shown in the drawing is an example and may be changed. In a state in which the first surface 600A is viewed, the main heat-generating portions formed in the semiconductor chip 600, for example, the core areas, which are for a CPU, a GPU, an NPU, etc., may overlap within the first area A1 that is surrounded by the first trench 611.

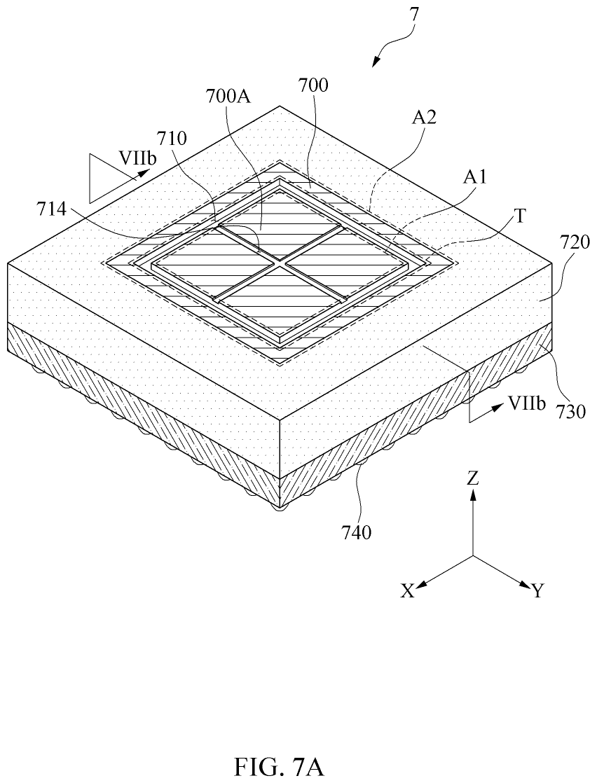

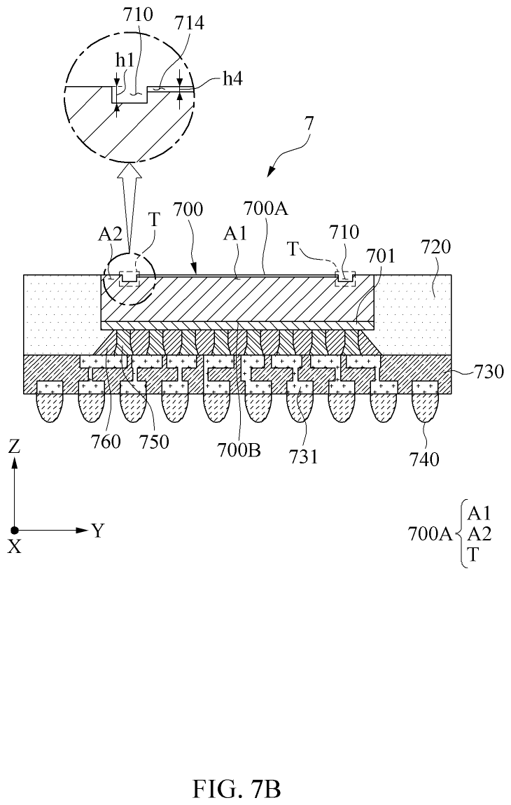

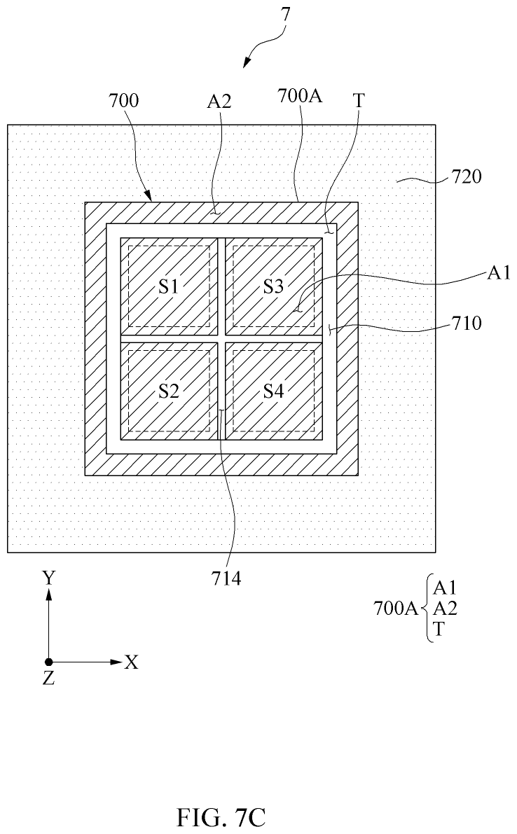

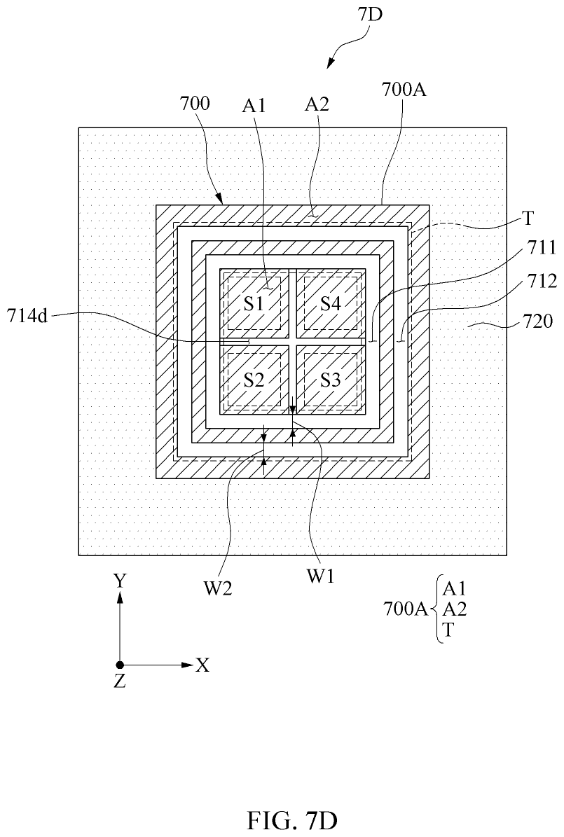

FIG. 7A is a perspective view of a semiconductor package according to an embodiment of the present inventive concept. FIG. 7B is a cross-sectional view of the semiconductor package, taken along line VIIb-VIIb, of FIG. 7A. FIG. 7C is a plan view of the semiconductor package according to an embodiment of the present inventive concept.

Referring to FIGS. 7A and 7B, a semiconductor package 7 according to an embodiment of the present inventive concept may include a semiconductor chip 700, a molding layer 720, a semiconductor substrate 730 on which a redistribution layer 731 is formed, and a plurality of bumps 750, an underfill layer 760, and a connecting terminal 740.

The semiconductor chip 700 may include a first surface 700A, which is an inactive surface that is disposed opposite the semiconductor substrate 730, and a second surface 700B, which is an active surface that is disposed to face toward the semiconductor substrate 730. A chip pad 701 may be disposed on the second surface 700B. The semiconductor chip 700 may be surrounded by the molding layer 720, and the molding layer 720 may be omitted from the first surface 700A. For example, the first surface 700A of the semiconductor chip 700 may be exposed to the outside of the semiconductor package 7.

The first surface 700A of the semiconductor chip 700 may include a trench area T, a first area A1, and a second area A2. The trench area T may be where a trench 710 is formed to be concave. The first area A1 may be surrounded by the trench area T, and the second area A2 may be positioned on the outer side of the trench area T. The trench 710 may form a closed loop in the trench area T, and the closed loop may be along the perimeter of the first area A1.

An auxiliary trench 714 may be formed to traverse the first area A1 in the first surface 700A of the semiconductor chip 700. The auxiliary trench 714 may be formed to be connected to the trench 710 formed in the trench area T. The auxiliary trench 714 may divide the first area A1 into a plurality of separate areas. The auxiliary trench 714 may be configured to accommodate a portion of the molding material as assistance to the trench 710 when the amount of molding material introduced into the trench 710 exceeds the capacity of the trench 710. For example, the depth h1 of the trench 710 that is formed in the trench area T may be greater than the depth h4 of the auxiliary trench 714 that is formed in the first area A1. The auxiliary trench 710 may reduce or prevent the inflow of molding material into a portion of the first area A1 where the auxiliary trench 710 is not formed.

Referring to FIG. 7C, in the semiconductor package 7, the semiconductor chip 700 may include a plurality of core areas S1, S2, S3, and S4 to perform different functions. It should be noted that the number and arrangement of core areas S1, S2, S3, and S4 are exemplary. The core areas S1, S2, S3, and S4 may exhibit the main heat generation characteristics in the semiconductor chip 700.

In a state in which the first surface 700A is viewed, the plurality of core areas S1, S2, S3, and S4 formed in the semiconductor chip 700 may overlap within the first area A1. For example, the trench 710 may be formed to surround the core areas S1, S2, S3, and S4 of the semiconductor chip 700. The auxiliary trench 714 may be formed in the first area A1 and might not to overlap the core areas S1, S2, S3, and S4 of the semiconductor chip 700, in a state in which the first surface 700A is viewed. When the molding material flows into the first surface 700A along the periphery of the first surface 700A during the process of forming the molding layer 720, the molding material may be introduced sequentially into the trench 710 and the auxiliary trench 714. Since the auxiliary trench 714 is formed not to overlap the main core areas S1, S2, S3, and S4 of the semiconductor chip 700, the inflow of the molding material into portions of the first area A1 corresponding to the main core areas S1, S2, S3, and S4 may be at least reduced or prevented.

FIG. 7D is a plan view of a semiconductor package according to an embodiment of the present inventive concept.

Referring to FIG. 7D, in a semiconductor package 7D according to an embodiment of the present inventive concept, a first surface 700A of a semiconductor chip 700 may be exposed to the outside and may be an inactive surface. The first surface 700A of the semiconductor chip 700 may be surrounded by a molding layer 720.

The first surface 700A of the semiconductor chip 700 may include a first area A1, a trench area T, and a second area A2. The first area A1 may overlap a plurality of core areas S1, S2, S3, and S4. The trench area T may surround the first area A1, and the second area A2 may surround the trench area T.

A first trench 711 and a second trench 712 may be formed in the trench area T. The first trench 711 may be concaved downward from the first surface 700A while surrounding the first area A1, and the second trench 712 may be spaced apart from the first trench 711 and concaved downward from the first surface 700A while surrounding the first trench 711. An auxiliary trench 714d may be formed to connect to the first trench 711 and traverse the first area A1. The auxiliary trench 714d may be formed in the first area A1 and might not to overlap the core areas S1, S2, S3, and S4 exhibiting the main heat generation characteristics in the semiconductor chip 700, in a state in which the first surface 700A is viewed.

The second trench 712 may primarily accommodate the molding material introduced into the first surface 700A during the process of forming the molding layer 720, and the first trench 711 may secondarily accommodate the molding material flowing from the second trench 712. The second trench 712 may be configured to accommodate a larger amount of molding material than the first trench 711. For example, the second trench 712 may be formed to have a second width W2 that is greater than the first width W1 of the first trench 711. When the molding material introduced into the first trench 711 exceeds the capacity of the first trench 711, the auxiliary trench 714d may additionally accommodate the molding material as assistance to the first trench 711.

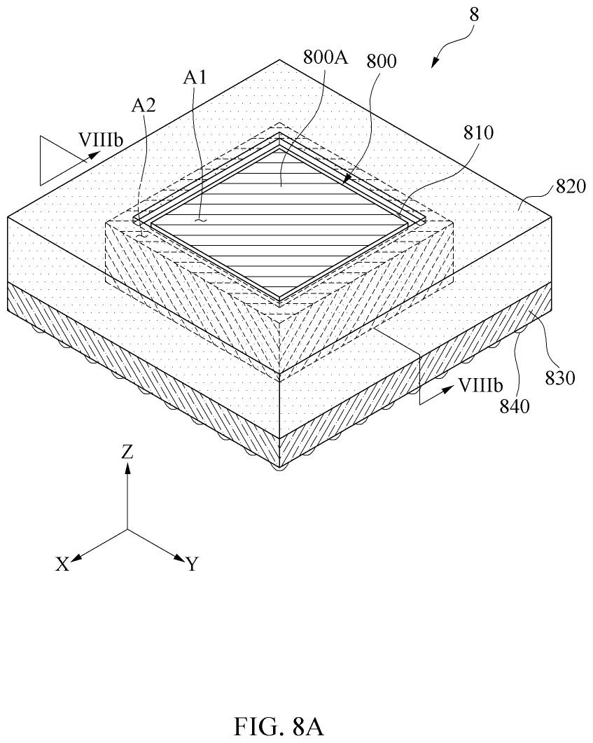

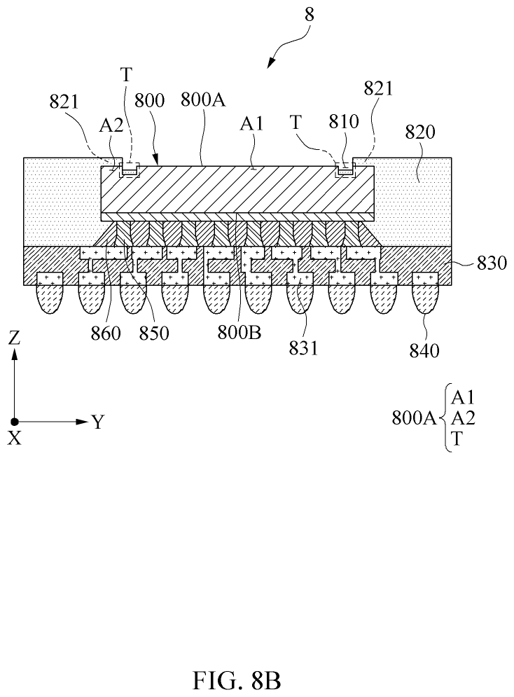

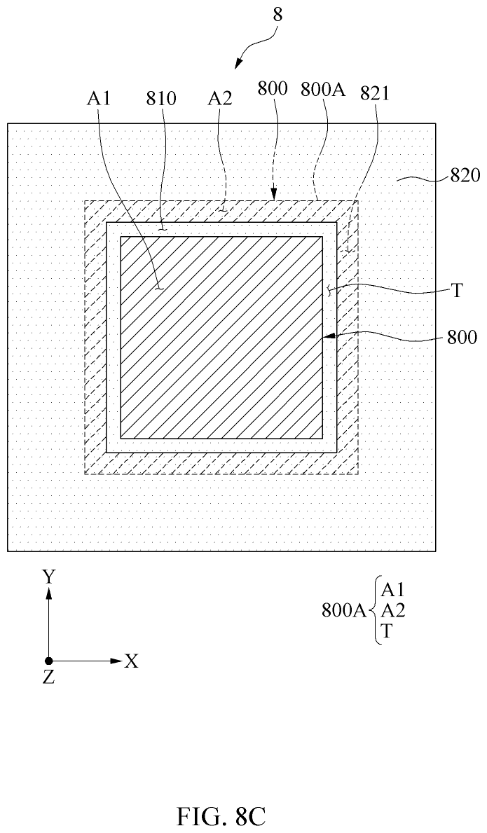

FIG. 8A is a perspective view of a semiconductor package according to an embodiment of the present inventive concept. FIG. 8B is a cross-sectional view of the semiconductor package, taken along line VIIIb-VIIIb, of FIG. 8A. FIG. 8C is a plan view of the semiconductor package according to an embodiment of the present inventive concept.

Referring to FIGS. 8A, 8B, and 8C, a semiconductor package 8 according to an embodiment of the present inventive concept may include a semiconductor chip 800, a molding layer 820 surrounding the semiconductor chip 800, a semiconductor substrate 830 on which a redistribution layer 831 is formed, a plurality of bumps 850 connecting the semiconductor chip 800 to the redistribution layer 831 of the semiconductor substrate 830, an underfill layer 860 disposed between the semiconductor chip 800 and the semiconductor substrate 830 to fill the gap that is between the plurality of bumps 850, and a connecting terminal 840.

The semiconductor chip 800 may include a first surface 800A, which is disposed opposite the semiconductor substrate 830, and a second surface 800B, which is disposed opposite the first surface 800A and faces toward the semiconductor substrate 830. A chip pad 801 may be disposed on the second surface 800B. The first surface 800A of the semiconductor chip 800 may be an inactive surface, and the second surface 800B may be an active surface. At least a portion of the first surface 800A of semiconductor chip 800 may be exposed to the outside. The first surface 800A of the semiconductor chip 800 may include a trench area T, a first area A1, and a second area A2. The trench area T may be where the trench 810 is formed, and a first area A1 may be surrounded by the trench area T. The second area A2 may extend from the outer side of the trench area T to the periphery of the first surface 800A. The trench 810 may be formed to be concaved downward from the first surface 800A.

The molding layer 820 may surround the semiconductor chip 800. At least a portion of the molding layer 820 may cover the first surface 800A of the semiconductor chip 800. For example, the molding layer 820 may include a cover portion 821 extending from the periphery of the first surface 800A of the semiconductor chip 800 toward the first area A1. The cover portion 821 may cover at least a portion of the first surface 800A of the semiconductor chip 800. The cover portion 821 may be formed by the molding material that is introduced into the first surface 800A of the semiconductor chip 800 during the process of molding the molding layer 820. The cover portion 821 may be disposed on the first surface 800A to cover at least a portion of the second area A2. For example, the cover portion 821 may cover the entire second area A2 of the first surface 800A as shown in FIG. 5C, or may be disposed to cover only a portion of the second area A2. In an example, at least a portion of the cover portion 821, for example, the molding layer 820, may be disposed inside the trench 810. The molding material that is disposed inside the trench 810 may be the molding material that is introduced across the second area A2 during the molding process.

The first surface 800A of the semiconductor chip 800 may be exposed to the outside through the first area A1 surrounded by the trench 810. For example, the molding layer 820 may be omitted from the first area A1. For example, the molding layer 820 does not cover the first area A1. The semiconductor chip 800 may secure heat dissipation performance through the first area A1.

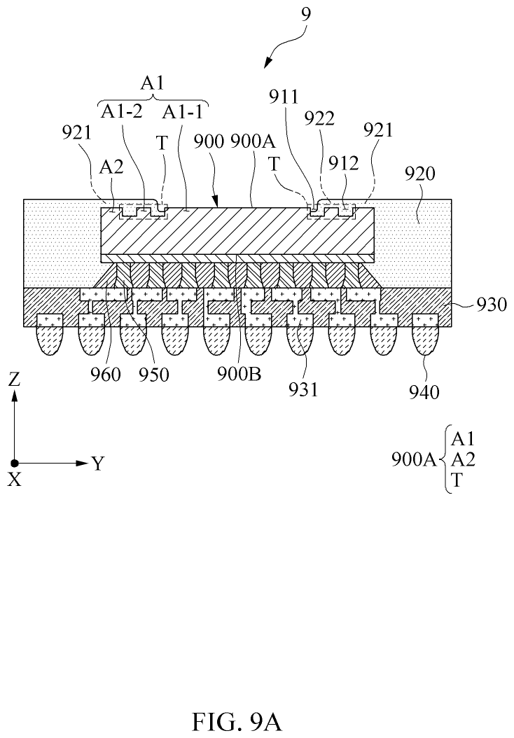

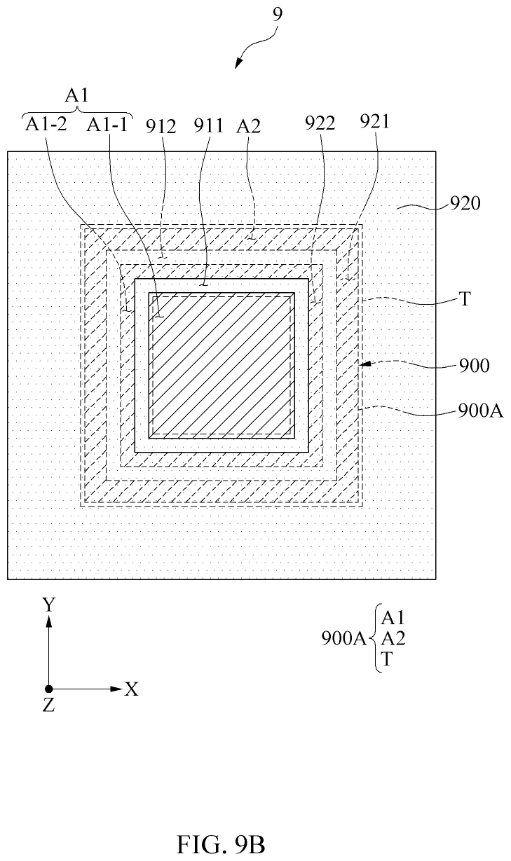

FIG. 9A is a cross-sectional view of a semiconductor package according to an embodiment of the present inventive concept. FIG. 9B is a plan view of the semiconductor package according to an embodiment of the present inventive concept.

A semiconductor package 9 according to an embodiment of the present inventive concept may include a semiconductor chip 900, a molding layer 920 surrounding the semiconductor chip 900, a semiconductor substrate 930 on which a redistribution layer 931 is formed, a plurality of bumps 950 connecting the semiconductor chip 900 to the redistribution layer 931 of the semiconductor substrate 930, an underfill layer 960 disposed between the semiconductor chip 900 and the semiconductor substrate 930 to fill the gap that is between the plurality of bumps 950, and a connecting terminal 940.

The semiconductor chip 900 may include a first surface 900A, which is disposed opposite the semiconductor substrate 930, and a second surface 900B, which is disposed opposite the first surface 900A and faces toward the semiconductor substrate 930. The first surface 900A of the semiconductor chip 900 may be an inactive surface, and the second surface 900B may be an active surface. At least a portion of the first surface 900A of the semiconductor chip 900 may be exposed to the outside. The first surface 900A of the semiconductor chip 900 may include a trench area T, a first area A1, and a second area A2. The trench area T may be where a plurality of trenches 911 and 912 are formed. The first area A1 may be surrounded by the trench area T, and the second area A2 may extend from the outer side of the trench area T to the periphery of the first surface 900A. The trenches 911 and 912 may be formed to be concaved downward from the first surface 900A.

A first trench 911 and a second trench 912 may be formed in the trench area T. The first trench 911 may surround the first area A1, and the second trench 912 may be spaced apart from the first trench 911 while surrounding the first trench 911. For example, the first trench 911 may form the boundary between the first area A1 and the trench area T, and the second trench 912 may form the boundary between the second area A2 and the trench area T.

The molding layer 920 may surround the semiconductor chip 900. The molding layer 920 may include cover portions 921 and 922 extending from the periphery of the first surface 900A of the semiconductor chip 900 toward the first area A1. The cover portions 921 and 922 may cover at least a portion of the semiconductor chip 900, for example, the second area A2 and the trench area T. The cover portions 921 and 922 may be formed through the molding material flowing into the first surface 900A of the semiconductor chip 900 during the process of molding the molding layer 920.

The cover portions 921 and 922 may include a first cover portion 921 and a second cover portion 922. The first cover portion 921 may extend across the second area A2 from the periphery of the first surface 900A, and the second cover portion 922 may connect to the first cover portion 921 and extend across the trench area T. The first cover portion 921 may cover at least a portion of the second area A2. The second cover portion 922 may extend across the second trench 912 to the first trench 911. In an example, at least a portion of the molding layer 920 may be disposed inside each of the first trench 911 and the second trench 912. The first surface 900A of the semiconductor chip 900 may be exposed to the outside through the first area A1 that is surrounded by the first trench 911. For example, the molding layer 920 may be omitted from the first area A1. The semiconductor chip 900 may secure heat dissipation performance through the first area A1.

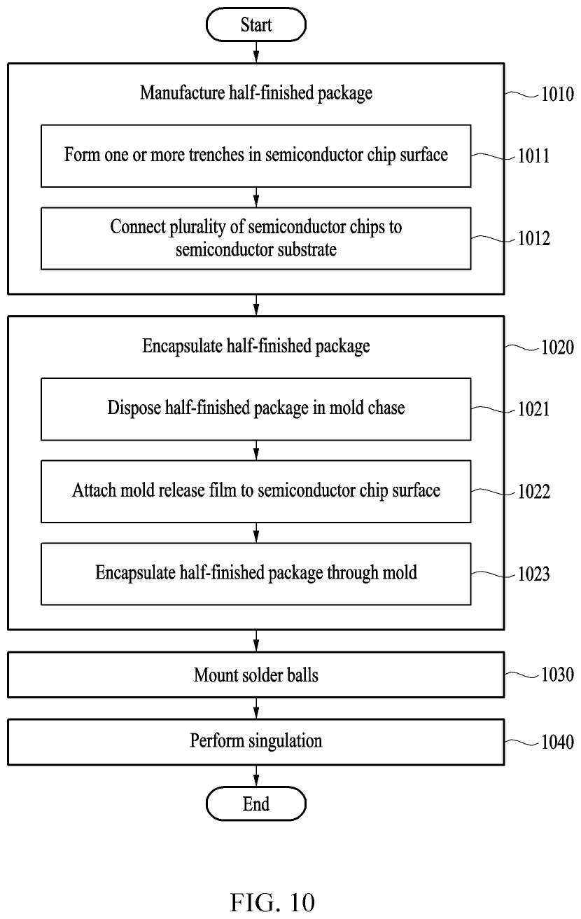

FIG. 10 is a flowchart of a semiconductor package manufacturing method according to an embodiment of the present inventive concept.

Referring to FIG. 10, a semiconductor package manufacturing method may be used to manufacture an exposed die package in which at least a portion of the surface of a semiconductor chip is exposed. A semiconductor package manufactured through the semiconductor package manufacturing method may be a BGA, for example, a fine-pitch ball grid array (FBGA).

It should be noted that, unless the order is specifically limited, the operations of the semiconductor package manufacturing method do not necessarily need to be performed sequentially. At least two of the operations of the semiconductor package manufacturing method may be performed simultaneously. At least one of the operations of the semiconductor package manufacturing method may be performed repeatedly.

The semiconductor package manufacturing method may include operation 1010 of manufacturing a half-finished package, operation 1020 of encapsulating the half-finished package, operation 1030 of mounting solder balls, and operation 1040 of performing singulation on a semiconductor package.

In operation 1010, a half-finished semiconductor in which a plurality of semiconductor chips are interconnected on a semiconductor substrate on which a redistribution layer is formed. Operation 1010 may include operation 1011 of forming one or more trenches in the surface of a semiconductor chip, and operation 1012 of connecting a plurality of semiconductor chips to a semiconductor substrate.

In operation 1011, trenches may be formed in an inactive surface of a semiconductor chip. The trenches may be formed in the shape of a closed loop along the periphery of the semiconductor chip. For example, the trenches may be formed to be concave in the inactive surface of the semiconductor chip through laser processing. In operation 1011, the plurality of trenches may be formed in the inactive surface of the semiconductor chip. For example, operation 1011 may include an operation of forming a first trench in the in-active surface of the semiconductor chip, and an operation of forming a second trench surrounding the first trench in the inactive surface of the semiconductor chip.

In operation 1012, a plurality of semiconductor chips may be connected to a semiconductor substrate. In operation 1012, the plurality of semiconductor chips may be spaced apart from each other and disposed with their active surfaces facing toward the semiconductor substrate. For example, in operation 1012, the semiconductor chips may be connected to the redistribution layer of the semiconductor substrate through a flip chip bonding process through bumps. In operation 1012, an underfill process may be performed to fill the space between the plurality of bumps with a polymer material. In operation 1010, operation 1011 may be performed before operation 1012, simultaneously with operation 1012, or after operation 1012.

In operation 1020, the manufactured half-finished package may be encapsulated by molding the half-finished package with a molding material. The molding material may include, for example, an EMC. In operation 1020, a molding layer surrounding the semiconductor chip may be formed by molding the half-finished package. Operation 1020 may include operation 1021, which is of disposing the half-finished package in a mold chase, operation 1022 of attaching a mold release film to the inactive surface of the semiconductor chip, and operation 1023, which is of encapsulating the half-finished package through a molding material.

In operation 1021, the half-finished package may be disposed in a mold chase. For example, the half-finished package may be disposed such that the semiconductor substrate is positioned on a lower mold chase. An upper mold chase may be disposed on the upper portions, for example, inactive surfaces, of the plurality of semiconductor chips. In operation 1022, a mold release film may be disposed on the inactive sides of the semiconductor chips. In operation 1023, a molding material including an EMC may be molded in the mold chase to form a molding layer that surrounds the semiconductor chip.

In operation 1030, solder balls may be mounted on the semiconductor package on which the molding layer is formed. The solder balls may be connected to the semiconductor chip.

In operation 1040, singulation may be performed on the semiconductor chips. Individual semiconductor packages may be formed by cutting the plurality of chips that are connected to the semiconductor substrate.

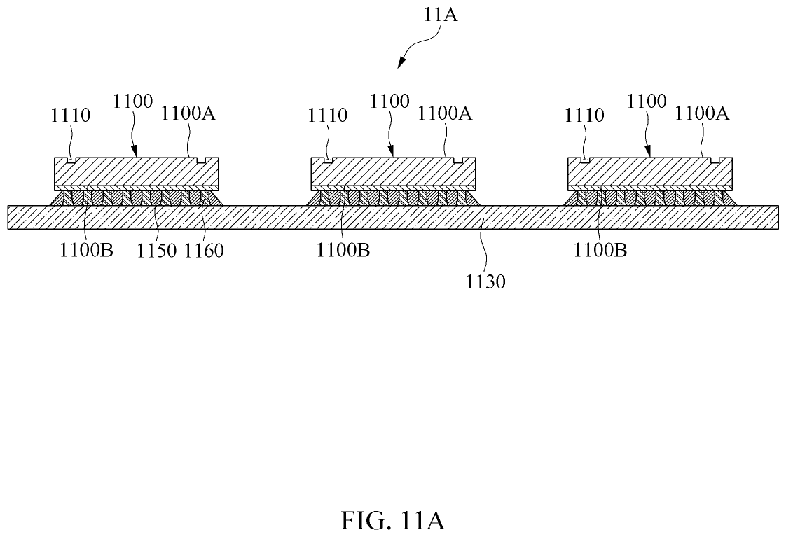

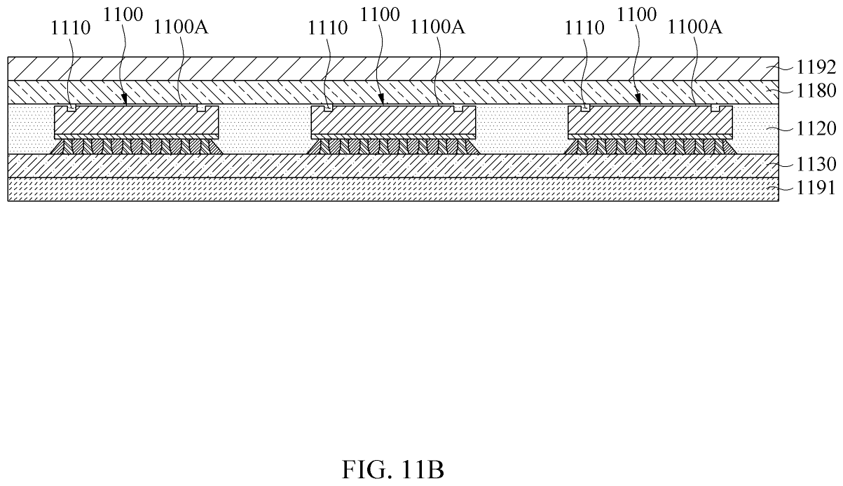

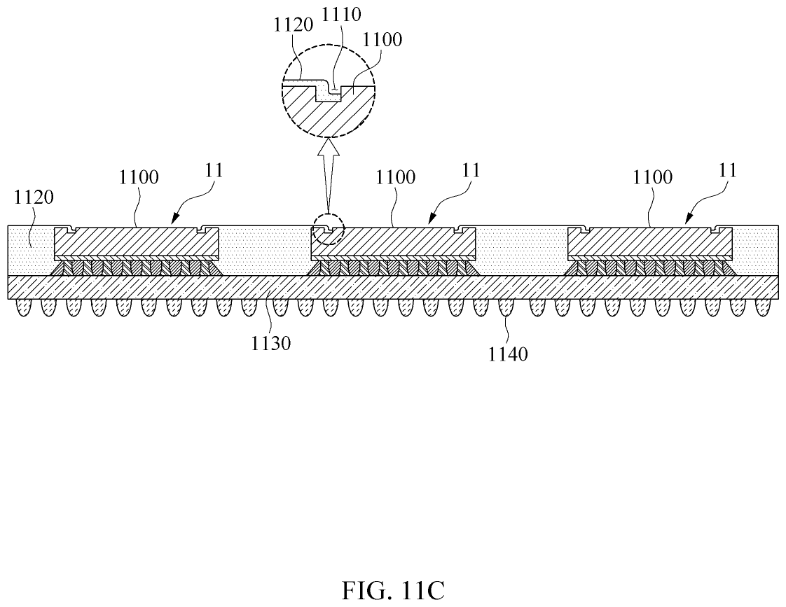

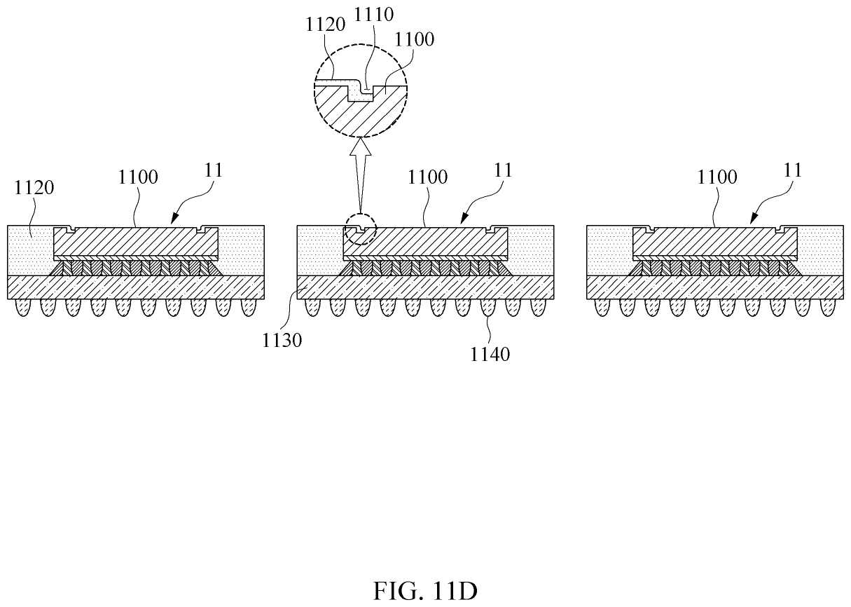

FIG. 11A illustrates a half-finished package manufactured by a package manufacturing process according to an embodiment of the present inventive concept. FIG. 11B illustrates an encapsulation process according to an embodiment of the present inventive concept. FIG. 11C illustrates a solder ball mounting process according to an embodiment of the present inventive concept. FIG. 11D illustrates a singulation process according to an embodiment of the present inventive concept.

Referring to FIGS. 11A to 11D, a series of operations in the process of manufacturing a semiconductor package will be described as an example.

Referring to FIG. 11A, a half-finished package 11A in which a plurality of semiconductor chips are connected to a semiconductor substrate 1130 may be manufactured. A semiconductor chip 1100 may include an inactive surface 1100A and an active surface 1100B that is opposite the inactive surface 1100A. The plurality of semiconductor chips 1100 may be disposed with the inactive surfaces 1100A toward the semiconductor substrate 1130. A semiconductor chip 1100 may be connected to the semiconductor substrate 1130 through flip chip bonding through a plurality of bumps 1150, and the space between the plurality of bumps 1150 may be filled with a polymer material 1160 through an underfill process. A trench having a closed loop shape may be formed in the inactive surface 1100A of the semiconductor chip 1100 along the periphery of the inactive surface 1100A. The trench may be formed to be concave in the inactive surface 1100A through, for example, laser processing.

Referring to FIG. 11B, the process of encapsulating the half-finished package may be performed. For example, the semiconductor substrate 1130 may be disposed on a lower mold chase 1191, and a mold release film 1180 may be attached to the inactive surfaces 1100A of the plurality of semiconductor chips 1100. An upper mold chase 1192 may cover the inactive surfaces 1100A of the semiconductor chips 1100. Thereafter, a molding material including an EMC may be introduced into the mold chases 1191 and 1192, and a molding layer 1120 that surrounds the semiconductor substrate 1130 may be formed through molding with the molding material. Since the inactive surfaces 1100A of the plurality of semiconductor chips 1100 are covered by the mold release film 1180 and the upper mold chase 1192, the molding layer 1120 may be omitted from the inactive surfaces 1100A of the semiconductor chips 1100.

Referring to FIG. 11C, a portion of the molding material may be introduced onto the inactive surfaces 1100A of the semiconductor chips 1100 through the gap that is between the semiconductor chips 1100 and the mold release film 1180, during the molding process due to the height difference between the plurality of semiconductor chips 1100, distortion of the mold release film 1180, and the like. The molding material that is introduced to the inactive surfaces 1100A of the semiconductor chips 1100 may be accommodated in trenches 1110 that are formed in the inactive surfaces 1100A, and the introduction of the molding material into the inner regions of the inactive surfaces 1100A may be reduced or prevented based on the trenches 1110 as the boundaries. After the molding process is completed, the molding layer 1120 may be formed on at least a portion of the inactive surfaces 1100A of the semiconductor chips 1100, but the molding layer 1120 may be omitted from portions of the inactive surfaces 1100A that is surrounded by the trenches 1110. After the molding process is completed, connecting terminals such as solder balls 1140 may be mounted on the semiconductor substrate 1130.

Referring to FIG. 11D, after the molding process and the solder ball mounting process are completed, a singulation process may be performed on the plurality of semiconductor chips 1100 based on their boundaries, so that a plurality of semiconductor packages 11 that are separated from each other may be manufactured.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package comprising:
a semiconductor substrate on which a redistribution layer is formed;
a semiconductor chip having a first surface that is disposed opposite the semiconductor substrate;
a bump connecting the semiconductor chip to the redistribution layer; and
a molding layer at least partially surrounding the semiconductor chip, wherein the first surface of the semiconductor chip comprises:
a trench area where one or more trenches, which have a closed loop shape and are concave, are positioned;
a first area surrounded by the trench area; and
a second area positioned on an outer side of the trench area, and
the first surface of the semiconductor chip is exposed to an outside of the molding layer at least through the first area.

2. The semiconductor package of claim 1, wherein
the one or more trenches are formed in the shape of a square ring along a perimeter of the first surface of the semiconductor chip, and
the one or more trenches comprise:
a plurality of first trench portions positioned at respective corners of the square ring; and
a plurality of second trench portions positioned on respective sides of the square ring to connect a pair of adjacent first trench portions of the plurality of first trenches.

3. The semiconductor package of claim 2, wherein
the first trench portions have a first width, and
the second trench portions have a second width that is smaller than that of the first trench portions.

4. The semiconductor package of claim 2, wherein the first trench portions are formed in a filleted shape.

5. The semiconductor package of claim 2, wherein the first trench portions are formed to have a depth that is greater than that of the second trench portions.

6. The semiconductor package of claim 1, wherein
a plurality of core areas, in which different functions are performed, are formed in the semiconductor chip, and
the one or more trenches are formed to surround a portion of the plurality of core areas so that the portion of the core areas are disposed within the first area.

7. The semiconductor package of claim 6, wherein the portion of the plurality of core areas that are disposed within the first area generates more heat than remaining core areas of the plurality of core areas.

8. The semiconductor package of claim 1, wherein the one or more trenches includes:
a first trench disposed in the trench area and surrounding the first area; and
a second trench spaced apart from the first trench while disposed in the trench area, and surrounding the first trench.

9. The semiconductor package of claim 8, wherein the second trench is formed to have a width that is greater than that of the first trench.

10. The semiconductor package of claim 8, wherein the second trench is formed to have a depth that is greater than that of the first trench.

11. The semiconductor package of claim 1, wherein
a plurality of core areas, in which different functions are performed, are located on a second surface of the semiconductor chip opposite to the first surface of the semiconductor chip, and
the plurality of core areas overlap in a vertical direction with the first area of the first surface of the semiconductor chip.

12. The semiconductor package of claim 1, wherein the semiconductor chip further comprises:
one or more auxiliary trenches disposed within the first area to be adjacent to the one or more trenches, and formed to be concave in the first surface.

13. The semiconductor package of claim 1, wherein the first surface of the semiconductor chip is coplanar with the upper surface of the molding layer.

14. The semiconductor package of claim 1, wherein
the molding layer covers the second area of the first surface of the semiconductor chip.

15. The semiconductor package of claim 1, wherein
the molding layer comprises a cover portion extending from a periphery of the semiconductor chip toward the first area, and
the cover portion is disposed to cover at least a portion of the second area.

16. The semiconductor package of claim 15, wherein at least a portion of the cover portion is positioned within the one or more trenches.

17. A semiconductor package comprising:
a semiconductor substrate on which a redistribution layer is formed;
a semiconductor chip having a first surface that is disposed opposite the semiconductor substrate;
a bump connecting the semiconductor chip to the redistribution layer; and
a molding layer at least partially surrounding the semiconductor chip, wherein
the semiconductor chip comprises:
a first trench formed to be concave in the first surface along a periphery of the semiconductor chip; and
a second trench formed to be concave in the first surface along the periphery of the semiconductor chip while surrounding the first trench,
wherein the first surface of the semiconductor chip comprises a first area and a second area,
wherein the first area is surrounded by the first trench,
wherein the second area extends from an outer side of the second trench, and
wherein the first surface of the semiconductor chip is exposed to an outer side of the molding layer at least through the first area.

18. The semiconductor package of claim 17, wherein
a plurality of core areas, in which different functions are performed, located on a second surface of the semiconductor chip opposite to the first surface of the semiconductor chip, and
the plurality of core areas overlap in a vertical direction with the first area of the first surface of the semiconductor chip.

19. A method of manufacturing a semiconductor package, the method comprising:
manufacturing a half-finished package in which a plurality of semiconductor chips are connected to a semiconductor substrate;
encapsulating the half-finished package by molding the half-finished package by using a molding material;
mounting a solder ball on the semiconductor substrate; and
performing singulation on the half-finished package, wherein
the manufacturing of the half-finished package comprises forming one or more trenches in inactive surfaces of the semiconductor chips along peripheries of the semiconductor chips.

20. The method of claim 19, wherein the forming of the one or more trenches comprises:
forming a first trench in the inactive surfaces of the semiconductor chips; and
forming a second trench that surrounds the first trench in the inactive surfaces of the semiconductor chips.
